(19) United States
(12) Patent Application Publication
(10) Pub. No.: US 2009/0269935 A1
(43) Pub. Date: Oct. 29, 2009

(54) Method of Forming Pattern of Semiconductor Device

(75) Inventor: CHUL CHAN CHOI, Anyang-si (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR, INC., Icheon-si (KR)

(21) Appl. No.: 12/163,570

(22) Filed: Jun. 27, 2008

(30) Foreign Application Priority Data
Apr. 24, 2008 (KR) 2008-38365

(51) Int. Cl. H01L 21/302

(52) U.S. Cl. 438/717; 257/E21.214

(57) ABSTRACT

A method of forming patterns of a semiconductor device, wherein a hard mask is formed over a semiconductor substrate; a photoresist comprising silicon-containing molecules is formed over the hard mask; a first exposure process is performed on first regions of the photoresist; a second exposure process is performed on second regions of the photoresist, which are located between the first regions; a bake process is performed on the photoresist; and, an etch process using the first regions and the second regions as etch mask patterns is performed, thereby patterning the photoresist and the hard mask.

### CROSS-REFERENCES TO RELATED APPLICATION

Priority to Korean patent application number 10-2008-0038365, filed on Apr. 24, 2008, the disclosure of which is incorporated by reference in its entirety, is claimed.

### BACKGROUND OF THE INVENTION

The invention relates to a method of forming patterns of a semiconductor device and, more particularly, to a method of forming micro patterns of a semiconductor device.

In the typical pattern formation process of a semiconductor device, a hard mask is formed on a specific target etch layer (for example, a silicon layer, an insulating layer, or a conductive layer) for forming patterns, and a photoresist (PR) layer is formed on the hard mask. A photolithography process is performed on the photoresist layer to thereby form photoresist patterns. The hard mask is patterned using the photoresist patterns as an etch mask, thereby forming hard mask patterns. The target etch layer is etched using the hard mask patterns, in order to form desired patterns.

However, with the high degree of integration of semiconductor devices, the design rule of a smaller critical dimension (CD) is applied. Thus, there is a need for techniques for forming a contact hole having a small opening size or a micro pattern having a narrow width. In accordance with this need, photolithography process technology for forming micro photoresist patterns for hard mask patterns has become increasingly important. Efforts continue to be made to form micro photoresist patterns by employing an ArF exposure system or a variety of image enhancement technologies.

### BRIEF SUMMARY OF THE INVENTION

The invention is directed to a method of forming patterns of a semiconductor device, suitable for forming micro patterns of smaller size in an etch target layer by employing silylated patterns as etch barriers. Accordingly, a silicon-containing photoresist is formed over an etch target layer, two exposure processes, preferably performed by shifting a reticle, are performed on the photoresist, and a bake process is then carried out in order to form the silylated patterns in the photoresist.

According to a method of forming patterns of a semiconductor device in accordance with an aspect of the invention, a hard mask is formed over a semiconductor substrate. A photoresist comprising silicon-containing molecules is formed over the hard mask. A first exposure process is performed on first regions of the photoresist. A second exposure process is performed on second regions of the photoresist, which are located between the first regions. A bake process is then performed on the photoresist. An etch process using the first regions and the second regions as etch mask patterns can then be performed, thus patterning the photoresist and the hard mask.

Preferably, the etch selectivity of only those regions of the photoresist on which the exposure and bake processes have been performed are selectively changed. The silicon-containing molecules preferably comprise 30 wt % to 80 wt % of the total amount of material constituting the photoresist. The photoresist preferably comprises a photoresist for KrF radiation or a photoresist for ArF radiation. The bake process is preferably performed at a temperature in the temperature range of 50 degrees Celsius to 300 degrees Celsius for 60 seconds to 300 seconds. The etch process is preferably performed using an anisotropic oxygen plasma etch method. The anisotropic oxygen plasma etch method is preferably performed using a bias power of 200 W to 1000 W. After the etch process is performed, the first regions, the second regions, and the photoresist are preferably removed. The first regions, the second regions, and the photoresist are preferably removed using an etch gas comprising N₂, O₂, and CF₄ gas. The CF₄ gas preferably comprises 10 vol % to 30 vol % based on the total amount of the etch gas. The first regions, the second regions, and the photoresist are preferably removed at a temperature in the temperature range of 100 degrees Celsius to 300 degrees Celsius. A bottom anti-reflective coating (BARC) layer is preferably formed between the photoresist and the hard mask. The first regions and the second regions preferably have the same pitch.

### BRIEF DESCRIPTION OF THE DRAWINGS

FIGS. 1A to 1F are sectional views illustrating a method of forming patterns of a semiconductor device in accordance with the invention.

### DESCRIPTION OF SPECIFIC EMBODIMENT

A specific embodiment according to the invention is described below with reference to the accompanying drawings. However, the scope of the invention is not limited to the disclosed embodiment, but may be implemented in various ways. The embodiment is provided to complete the disclosure of the invention and to allow those having ordinary skill in the art to understand the scope thereof. The scope of the invention is defined only by the appended claims.

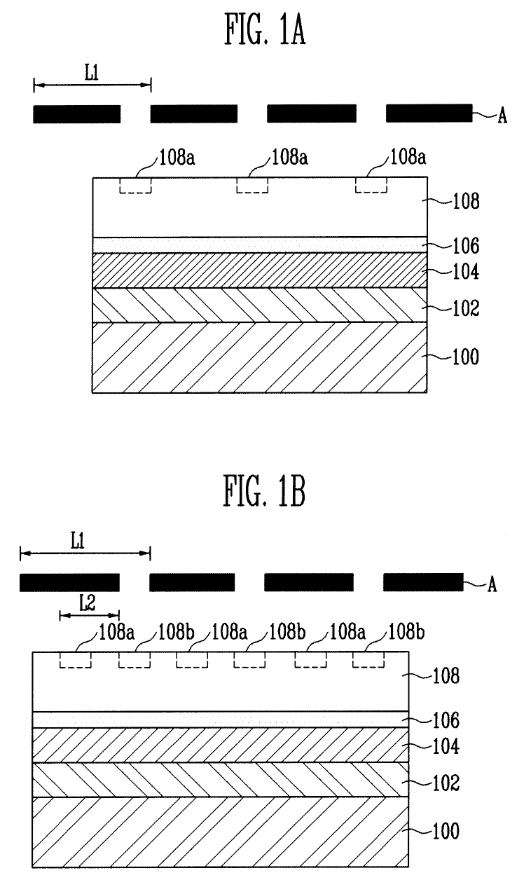

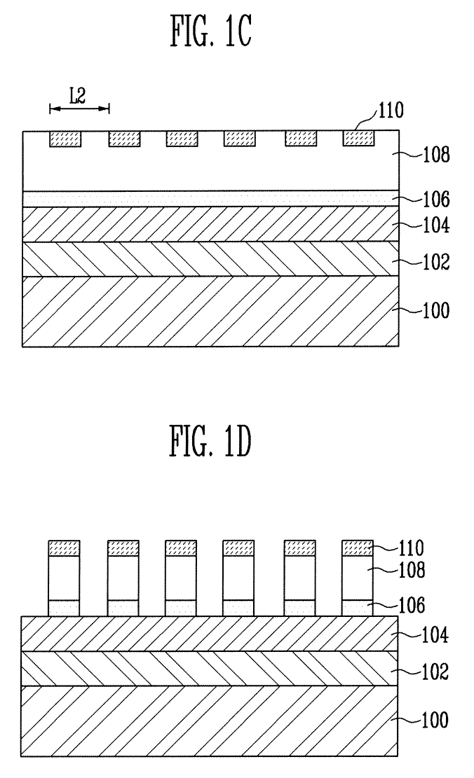

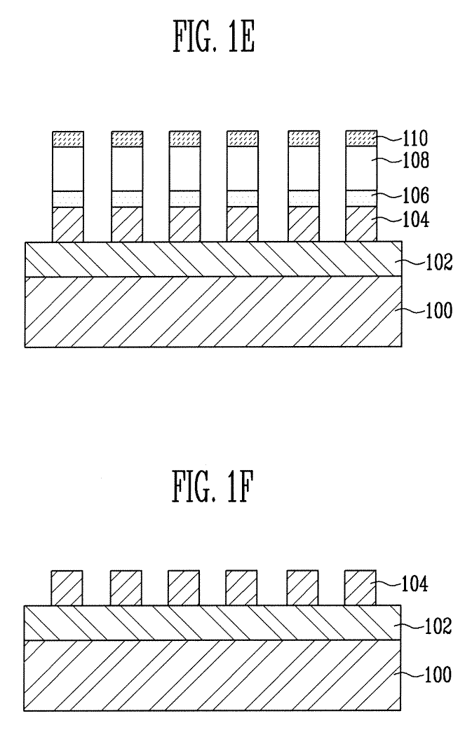

FIGS. 1A to 1F are sectional views illustrating a method of forming patterns of a semiconductor device in accordance with the invention.

Referring to FIG. 1A, a target etch layer 102 (for example, a conductive layer or an insulating layer) where patterns will be formed is formed on a semiconductor substrate 100. A hard mask 104 is formed on the target etch layer 102. To perform a photolithography process for patterning the hard mask 104, a bottom anti-reflective coating (BARC) layer 106 and a photoresist 108 are preferably formed over the hard mask 104.

The photoresist 108 preferably comprises a photoresist for KrF radiation or a photoresist for ArF radiation. The photoresist 108 is preferably formed of material whose etch selectivity can be changed by employing silylation that selectively changes the diffusivity characteristic of a surface through exposure and bake processes. In other words, the photoresist 108 can be formed from material containing silicon-containing molecules so that the diffusivity characteristic of the silicon-containing molecules can be changed in exposed portions. The silicon-containing molecules are used in an amount of 30 wt % to 80 wt % based on the total amount of the material constituting the photoresist 108.

Next, a first exposure process is performed on the photoresist 108, illustratively and preferably by employing a reticle A having light-transparent patterns having a pitch L1. Here, the pitch L1 of the light-transparent patterns formed in the reticle A corresponds to a size which can be formed within a range of the limited resolution of a typical exposure process. The pitch L1 is preferably twice the pitch of patterns formed in the target etch layer 102. Thus, first regions 108a where the diffusivity characteristic of silicon-containing molecules has been changed in response to the light-transparent patterns of the reticle A are formed to have the pitch L1 at exposed portions of the photoresist 108. The first exposure process is preferably performed using a KrF light source or an ArF light source using an appropriate photoresist material.

Referring to FIG. 1B, the reticle A is shifted laterally so that the light-transparent patterns of the reticle A are located between the first regions 108a. A second exposure process is performed on the photoresist 108 using the reticle A, thus forming second regions 108b having a pitch L1 between the first regions 108a. Therefore, the first regions 108a and the second regions 108b, having a pitch L2, can be formed in the photoresist 108. The pitch L2 of the first regions 108a and the second regions 108b formed in the photoresist 108 are illustratively and preferably half the pitch L1 of the light-transparent patterns formed in the reticle A, thus enabling the formation of more micro patterns. The second exposure process is preferably performed using a KrF light source or an ArF light source with an appropriate photoresist material.

Referring to FIG. 1C, a bake process is performed on the photoresist 108 in order to induce silylation of the exposed first regions (refer to 108a of FIG. 1B) and the exposed second regions (refer to 108b of FIG. 1B). Thus, the first regions (refer to 108a of FIG. 1B) and the second regions (refer to 108b of FIG. 1B) formed in the photoresist 108 are silylated, and thereby deformed into etch mask patterns 110.

The etch mask patterns 110 have an etch selectivity different from that of other photoresist 108 on which the exposure and bake processes have not been performed and, therefore, can serve as an etch barrier when etching the underlying layers in a subsequent process. The pitch L2 of the etch mask patterns 110 is illustratively half the pitch L1 of the light-transparent patterns formed in the reticle (refer to A of FIG. 1B), so that more micro patterns can be formed when etching the underlying layers. The bake process is preferably performed in a temperature range of 50 degrees Celsius to 300 degrees Celsius for 60 seconds to 300 seconds.

Referring to FIG. 1D, the photoresist 108 and the BARC layer 106 are etched and patterned by an etch process using the etch mask patterns 110 as the etch barrier. The etch process for patterning the photoresist 108 and the BARC layer 106 is preferably performed using an anisotropic oxygen plasma etch method, preferably employing a bias power of 200 W to 1000 W.

Referring to FIG. 1E, the hard mask 104 is etched and patterned by an etch process using the etch mask patterns 110, the photoresist 108, and the BARC layer 106 as an etch barrier. Thus, the hard mask 104 can form more micro patterns than the light-transparent patterns formed in the reticle (refer to A of FIG. 1B).

Referring to FIG. 1F, the etch mask patterns (refer to 110 of FIG. 1E), the photoresist (refer to 108 of FIG. 1E), and the BARC layer (refer to 106 of FIG. 1E) are removed. To this end, a photoresist (PR) strip process is preferably performed using an etch gas, preferably comprising N₂, O₂ and CF₄ gas, preferably in a temperature range of 100 degrees Celsius to 300 degrees Celsius. The CF₄ gas is preferably used in an amount of 10 vol % to 30 vol % based on the total amount of the etch gas. Thereafter, in order to remove impurities, a cleaning process is preferably further performed.

With the high degree of integration of semiconductor devices, the need for technologies for forming micro patterns has increased. Of those technologies, a technology such as a double patterning process has been introduced. However, the double patterning process is inconvenient because a patterning process in which an exposure process, an etch process, a PR strip process, and a cleaning process are sequentially performed must be carried out twice. There are also difficulties in that material used as an etch barrier must be newly formed, patterns formed between already formed patterns must be aligned, etc. Consequently, the double patterning process is problematic in that the turnaround time is increased and a complicated process is required, other than the simple twice-patterning processes.

However, in the case of the invention, by performing the bake process without performing a development process after the first exposure process and the second exposure process are performed, micro patterns similar to those formed by the double patterning process can be formed. Accordingly, the turnaround time can be shortened and the process can be simplified.

According to the method of forming patterns of a semiconductor device in accordance with the invention, after the two exposure processes, the bake process is performed and a development process is omitted. Therefore, more micro patterns than the resolution of an exposure system can be formed and micro patterns can be more easily formed. Consequently, semiconductor devices with a smaller size and a further improved performance can be fabricated using the simple and stable process of the invention.

The embodiment disclosed herein has been proposed to allow a person skilled in the art to easily implement the invention, and the person skilled in the part may implement the invention in various ways. Therefore, the scope of the invention is not limited by or to the embodiment as described above, and should be construed to be defined only by the appended claims and their equivalents.

What is claimed is:

1. A method of forming patterns of a semiconductor device, the method comprising:
forming a hard mask over a semiconductor substrate;
forming a photoresist over the hard mask, said photoresist comprising silicon-containing molecules;
performing a first exposure process on first regions of the photoresist;
performing a second exposure process on second regions of the photoresist, said second regions being located between the first regions;
performing a bake process on the photoresist; and
performing an etch process using the first photoresist regions and the second photoresist regions as etch mask patterns, thereby patterning the photoresist and the hard mask.

2. The method of claim 1, comprising selectively changing the etch selectivity of only those regions of the photoresist on which the exposure and bake processes have been performed.

3. The method of claim 1, wherein the silicon-containing molecules comprise 30 wt % to 80 wt % of the total amount of material constituting the photoresist.

4. The method of claim 1, wherein the photoresist comprises a photoresist for KrF radiation or a photoresist for ArF radiation.

5. The method of claim 1, comprising performing the bake process at a temperature in the range of 50 degrees Celsius to 300 degrees Celsius for 60 seconds to 300 seconds.

6. The method of claim 1, comprising performing the etch process using an anisotropic oxygen plasma etch method.

7. The method of claim 6, comprising performing the anisotropic oxygen plasma etch method using a bias power of 200 W to 1000 W.

8. The method of claim 1, further comprising removing the first regions, the second regions, and the photoresist after performing the etch process.

9. The method of claim 8, comprising removing one or more of the first regions, the second regions, and the photoresist using an etch gas comprising N₂, O₂, and CF₄ gas.

10. The method of claim 9, wherein the CF₄ gas comprises 10 vol % to 30 vol % based on the total amount of the etch gas.

11. The method of claim 8, comprising removing the first regions, the second regions, and the photoresist at a temperature in the range of 100 degrees Celsius to 300 degrees Celsius.

12. The method of claim 8, comprising removing the first regions, the second regions, and the photoresist using an etch gas comprising N₂, O₂, and CF₄ gas.

13. The method of claim 12, wherein the CF₄ gas comprises 10 vol % to 30 vol % based on the total amount of the etch gas.

14. The method of claim 1, further comprising forming a bottom anti-reflective coating (BARC) layer between the photoresist and the hard mask.

15. The method of claim 1, wherein the first regions and the second regions have the same pitch.
